(19) United States
(12) Patent Application Publication
(10) Pub. No.: US 2016/0336339 A1
(43) Pub. Date: Nov. 17, 2016

(54) DEVICE AND METHOD FOR DETERMINING ELECTRICAL CHARACTERISTICS FOR ELLIPSE GATE-ALL-AROUND FLASH MEMORY

(71) Applicant: Macronix International Co., Ltd., Hsinchu (TW)

(72) Inventors: Cheng-Hsien Cheng, Xiluo Township (TW); Chih-Wei Lee, New Taipei City (TW); Shaw-Hung Ku, Hsinchu City (TW); Wen-Pin Lu, Chupei (TW)

(21) Appl. No.: 14/881,350

(22) Filed: Oct. 13, 2015

Related U.S. Application Data
(60) Provisional application No. 62/161,332, filed on May 14, 2015.

(51) Int. Cl. H01L 27/115; G11C 16/14; H01L 29/792; H01L 29/51; H01L 29/423; G11C 16/04; G11C 5/06

(52) U.S. Cl. CPC H01L 27/11582; G11C 16/0483; G11C 16/14; G11C 16/0466; G11C 5/063; H01L 27/11565; H01L 29/511; H01L 29/42356; H01L 29/7926

(57) ABSTRACT

Embodiments of the present invention provide improved 3D non-volatile memory devices and associated methods. In one embodiment, a string of 3D non-volatile memory cells is provided. The string comprises a core extending along an axis of the string, the core having an elliptical cross section in a plane perpendicular to the axis; and a plurality of word lines, each word line disposed around a part of the core, the plurality of word lines spaced along the axis, and each word line corresponding to one of the memory cells. In various embodiments, at least one operating parameter is defined in order to improve the operation of the 3D non-volatile memory device.

### CROSS-REFERENCE TO RELATED APPLICATIONS

This application claims the benefit of U.S. Provisional Application No. 62/161,332 filed May 14, 2015, the content of which is incorporated by reference herein in its entirety.

### TECHNOLOGICAL FIELD

Embodiments of the present invention relate generally to semiconductor devices and, in particular, methods for determining electrical characteristics for gate-all-around (GAA) flash memory.

### BACKGROUND

A flash memory device (e.g., non-volatile semiconductor device) may generally be classified as NOR or NAND flash memory devices. Such flash memory devices may stack cells, or layers, on top of each other taking the form of a 3D architecture. In vertical NAND strings, each layer may have a different diameter due to a non-perfect process (e.g., a process utilizing a non-normal etching angle)<90°.

With respect to 3D NAND flash memory associated with circular cells, a perfectly cylinder-shaped hole or circular cell may provide highly symmetric architecture with identical electrical characteristics in each segment. However, process variation, nevertheless, may cause non-circle shapes. Because it is difficult to get a uniform hole along one string due to non-perfect processes, the electrical characteristics from the top cells to the bottom cells may be extremely different for non-circle shapes. Various models have been proposed to analyze GAA memory characteristics, including current-voltage (I-V) characteristics and program/erase transient on an ideally circular shape.

Accordingly, there is a need in the art to provide for the determination of electrical characteristics corresponding to non-volatile memory devices, such as 3D NAND devices, having GAA structures corresponding to non-circle shapes structures.

### BRIEF SUMMARY OF EXEMPLARY EMBODIMENTS

Embodiments of the present invention provide methods for determining electrical characteristics corresponding to a non-volatile memory device, such as 3D NAND flash memory, having a gate-all-around structure.

In one aspect of the present invention, a string of 3D memory cells is provided. According to various embodiments, the string comprises a core extending along an axis of the string, the core having an elliptical cross section in a plane perpendicular to the axis; a plurality of word lines, each word line disposed around a part of the core, the plurality of word lines spaced along the axis, and each word line corresponding to one of the memory cells. In some embodiments, the string comprises a first cell having a first elliptical cross section in a first plane perpendicular to the axis, the elliptical cross section defining a first major axis and a first minor axis; and a second cell having a second elliptical cross section in a second plane perpendicular to the axis, the elliptical cross section defining a second major axis and a second minor axis. The first cell and the second cell are neighboring cells, and at least one of the first and second major axes are different or the first and second minor axes are different.

According to another aspect of the present invention a method for improving a performance of a 3D non-volatile memory device comprising a plurality of cells having a gate-all-around structure is provided. In one embodiment, the method comprises determining at least one operating parameter of at least one of the plurality of cells. Determining the at least one operating parameter comprises determining at least one electrical characteristic of the at least one of the plurality of cells. According to one embodiment, determining an electrical characteristic of the at least one of the plurality of cells comprises defining a plurality of segments, the plurality of segments structured to define a closed loop, the closed loop approximating the circumference of the cross section of the cell; acquiring a radius of curvature for each of the plurality of segments; determining a value for the electrical characteristic for each of the plurality of segments based at least in part on the radius of curvature corresponding to the segment; and summing the values for the electrical characteristic for each of the plurality of segments to determine the electrical characteristic for the closed loop. The defining the at least one operating parameter further comprises defining an operating parameter of the at least one of the plurality of cells based at least in part on the determined electrical characteristic for the closed loop. The method further comprises causing at least one function to be performed on the cell in accordance with the defined operating parameter.

The above summary is provided merely for purposes of summarizing some example embodiments to provide a basic understanding of some aspects of the invention. Accordingly, it will be appreciated that the above-described embodiments are merely examples and should not be construed to narrow the scope or spirit of the invention in any way. It will be appreciated that the scope of the invention encompasses many potential embodiments in addition to those here summarized, some of which will be further described below.

### BRIEF DESCRIPTION OF THE SEVERAL VIEWS OF THE DRAWINGS

Having thus described certain example embodiments of the present disclosure in general terms, reference will now be made to the accompanying drawings, which are not necessarily drawn to scale, and wherein:

FIG. 1A illustrates a perspective view of an example string of an example non-volatile memory device that may be used in accordance with embodiments of the present invention;

FIG. 1B is a cross-sectional view of the string shown in FIG. 1A;

FIG. 2 provides a diagram of an example elliptical structure according to an embodiment of the invention;

FIG. 3 is a flowchart illustrating a process for determining electrical characteristics corresponding to a non-volatile memory device having a gate-all-around (GAA) structure according to an embodiment of the invention;

FIG. 4 illustrates a algorithm according to an embodiment of the invention;

FIG. 5 provides a flowchart illustrating an example process for determining the voltage distribution in accordance with an embodiment of the invention;

FIG. 6a illustrates an example graph of current-voltage characteristic corresponding to an elliptical structure according to an embodiment of the invention;

FIG. 6b illustrates an example graph of current-voltage characteristic corresponding to a circular structure according to an embodiment of the invention;

FIG. 7a illustrates an example graph of program transient corresponding to an elliptical structure according to an embodiment of the invention;

FIG. 7b illustrates an example graph of program transient corresponding to a circular structure according to an embodiment of the invention; and

FIG. 8 provides a block diagram of a computing system in accordance with various embodiments of the present invention.

### DETAILED DESCRIPTION

Some embodiments of the present invention will now be described more fully hereinafter with reference to the accompanying drawings, in which some, but not all embodiments of the invention are shown. Indeed, various embodiments of the invention may be embodied in many different forms and should not be construed as limited to the embodiments set forth herein; rather, these embodiments are provided so that this disclosure will satisfy applicable legal requirements.

Although specific terms are employed herein, they are used in a generic and descriptive sense only and not for purposes of limitation. All terms, including technical and scientific terms, as used herein, have the same meaning as commonly understood by one of ordinary skill in the art to which this invention belongs unless a term has been otherwise defined. It will be further understood that terms, such as those defined in commonly used dictionaries, should be interpreted as having a meaning as commonly understood by a person having ordinary skill in the art to which this invention belongs. It will be further understood that terms, such as those defined in commonly used dictionaries, should be interpreted as having a meaning that is consistent with their meaning in the context of the relevant art and the present disclosure. Such commonly used terms will not be interpreted in an idealized or overly formal sense unless the disclosure herein expressly so defines otherwise.

As used herein, “gate structure” refers to a component of a semiconductor device, such as a memory device. Non-limiting examples of memory devices include flash memory devices (e.g., a NAND flash memory device). Erasable programmable read-only memory (EPROM) and electrically erasable read-only memory (EEPROM) devices are non-limiting examples of flash memory devices. The gate structures of the invention may be a gate structure assembly capable of operating in memory devices or a sub-assembly of a component or components of such gate structures.

As used herein, a “non-volatile memory device” refers to a semiconductor device which is able to store information even when the supply of electricity is removed. Non-volatile memory includes, without limitation, mask read-only memory (MROM), programmable read-only memory (PROM), erasable programmable read-only memory (EPROM), electrically erasable programmable read-only memory (EEPROM), and flash memory, such as NAND and NOR flash memory.

The gate structure (e.g., a non-volatile memory device) of the invention and methods provide for determining electrical characteristics corresponding to a non-volatile memory device, such as 3D NAND flash memory, having a gate-all-around structure corresponding to a non-circular structure (e.g., a GAA structure comprising a plurality of points configured to form a plurality of segments structured to define a closed loop, such as an elliptical structure).

### Exemplary 3D Memory Architecture

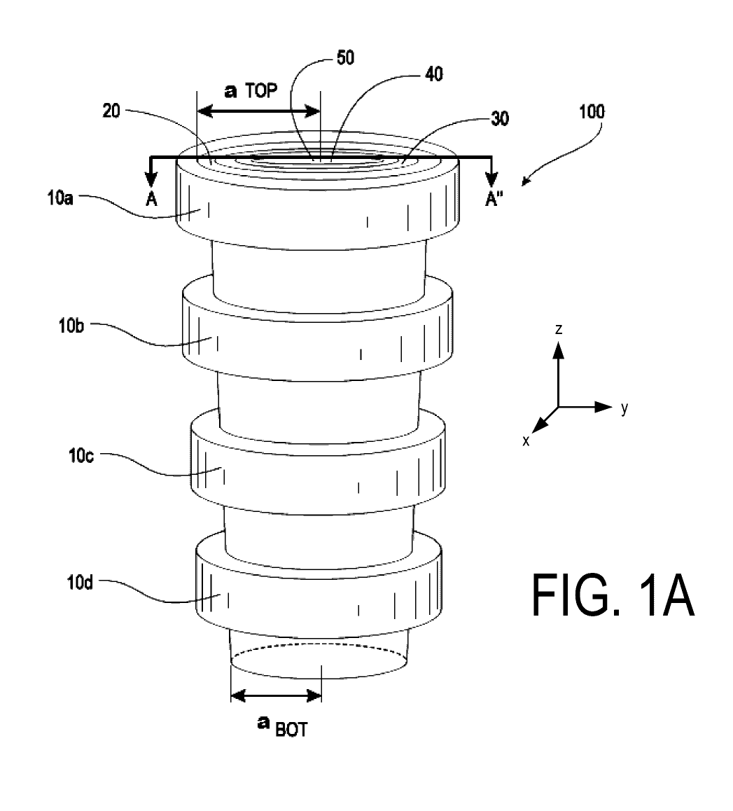

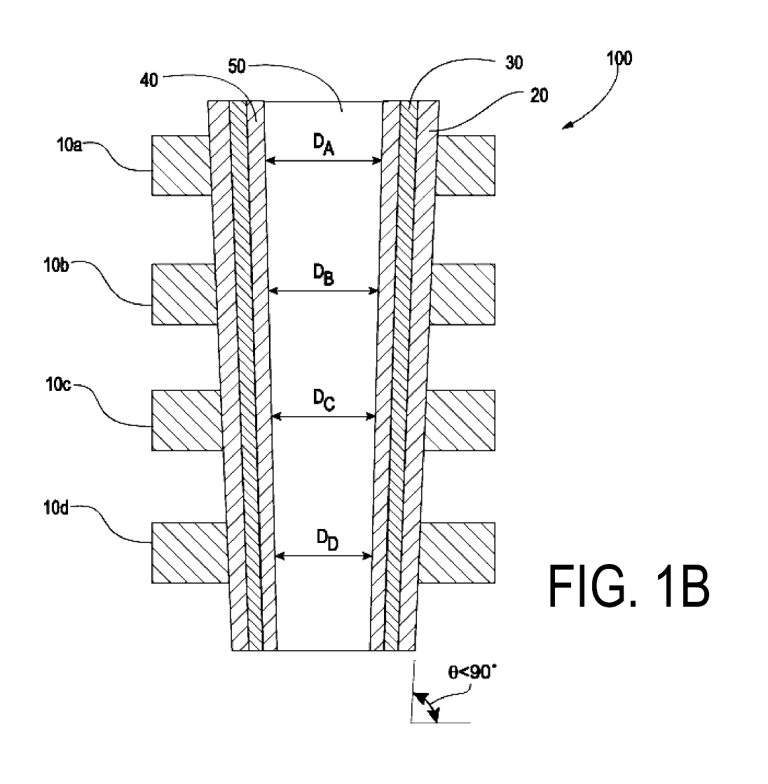

FIGS. 1A and 1B illustrate a portion of a non-volatile memory device (e.g., 3D NAND flash memory) in accordance with various embodiments of the present invention. The illustrated portion of the non-volatile memory device comprises a vertical string 100, comprising a plurality of memory cells. The illustrated string 100 comprises four cells; however, in various embodiments, the string 100 may comprise more than four cells or less than four cells, as appropriate for the application. In general, the string 100 comprises a generally cylindrical portion having word lines 10a, 10b, 10c, and 10d (e.g., one word line corresponding to each cell) wrapped there around. It's important to note that while the string 100 is generally cylindrical, it is actually slightly conical. The process through which the layers of the string are etched causes the string to be slightly off from normal. Thus, the exterior angle, θ, is less than 90°. This causes the radius at the top of the string, a_{TOP}, to be greater than the radius at the bottom of the string, a_{BOT}. Thus, the channel width for each cell of the string 100 differs from the neighboring cell channel width (e.g., D_{A}>D_{B}>D_{C}>D_{D}).

In various embodiments, the vertical string 100 may have an elliptical cross section in a plane perpendicular to the axis of the vertical sting 100. Thus, the cells of the vertical string 100 may have an elliptical cross section in a plane perpendicular to the axis of the vertical string 100. The radius of the string (e.g., a_{BOT}, a_{TOP}) and/or the cell channel width (e.g., D_{A}, D_{B}, D_{C}, D_{D}) may be measured along the major axis of the elliptical cross section. As noted above the cell channel width of neighboring cells may differ. In particular if a first cell and a second cell are neighboring cells, they may each have an elliptical cross section perpendicular to the axis of the vertical string 100. The cross section of the first cell defines a first major axis and a first minor axis. The cross section of the second cell defines a second major axis and a second minor axis. In various embodiments, at least one of the first and second major axes are different (e.g., the first major axis is longer than the second major axis or vice versa) or the first and second minor axes are different (e.g., the first minor axis is longer than the second minor axis or vice versa).

In general, the NAND string 100 comprises a core comprising a tunnel layer 40, a trapping layer 30, and a blocking layer or dielectric layer 20 wrapped around a channel region 50. In various embodiments, the tunnel layer 40 may be made of oxide and be approximately 5 nm thick. In some embodiments, the blocking or dielectric layer 20 may be made of oxide and be approximately 7 nm thick. The channel region 50 may comprise polysilicon material or other appropriate material. Word lines (e.g., 10a, 10b, 10c, and 10d) are wrapped around the blocking or dielectric layer 20 such that there is one word line per cell. The word lines (e.g., 10a, 10b, 10c, and 10d) may be made of a polysilicon material, metal, or other appropriate material.

It is generally preferred that a cross section of the string 100 perpendicular to the z-axis is circular, due to the constant electrical field the circular architecture would provide. However, in various embodiments, the cross section of the string 100 may be non-circular (e.g., elliptical). For example, the cross section of the string 100 may be non-circular (e.g., elliptical) due to process variation. Various embodiments of the present invention provide a tool for understanding the effect of the non-circular cross section of the string 100 on the electrical performance of the string 100 and the cells comprising the string 100.

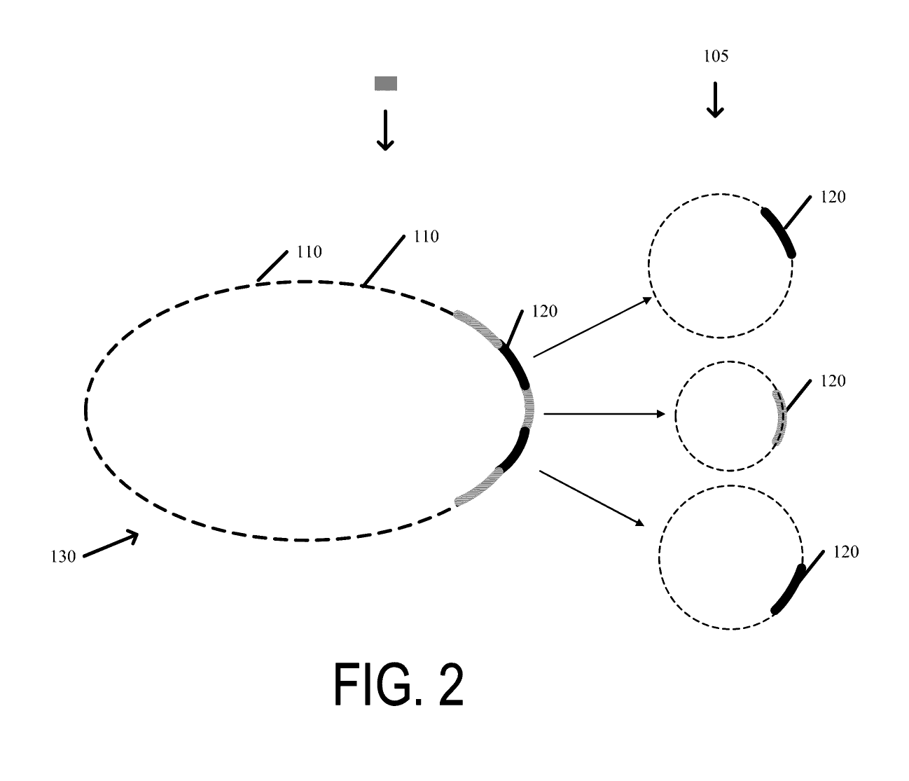

FIG. 2 provides a diagram of an example elliptical structure 101 representing and/or modeling a cross section of a string 100 perpendicular to the z-axis. In the example embodiments described herein, the cross-section of the string 100 is described as being elliptical; however, the cross section may have various shapes. As depicted, the elliptical structure 101 (e.g., a non-circular shaped GAA structure) comprises a plurality of points 110 configured to form a plurality of segments 120 structured to define a closed loop 130. Each segment 120 may be regarded as part of a circle 105 defined by a radius R, wherein the radius R is the curvature radius for the segment 120, as illustrated in FIG. 2. In various embodiments, the plurality of segments 120 may be determined based on a predetermined segment length, based on a predetermined bisected angle, based on the radius R (e.g., segments having a smaller R may be shorter or having a small bisected angle than segments having a larger R), and/or the like. At least one radius and/or curvature corresponding to each segment may then be determined. In this regard, electrical characteristics (e.g. electric field E, capacitance C, voltage distribution Vt) corresponding to each segment and/or radius may be determined.

The elliptical structure 101 may comprise at least two integration points (not shown), wherein a sum of a plurality of distances to the at least two integration points is configured to be constant for each point of the plurality of points 110 along the closed loop 130. GAA structures comprising an elliptical shape introduce complicated characteristics due to a plurality of segments 120 of less symmetry. Therefore, the electrical characteristics from the top cells differ from those of the bottom cells. For example, the properties of the cell defined by word line 10a may be different from those of the cell defined by word line 10d due to the difference in cross section of the two cells.

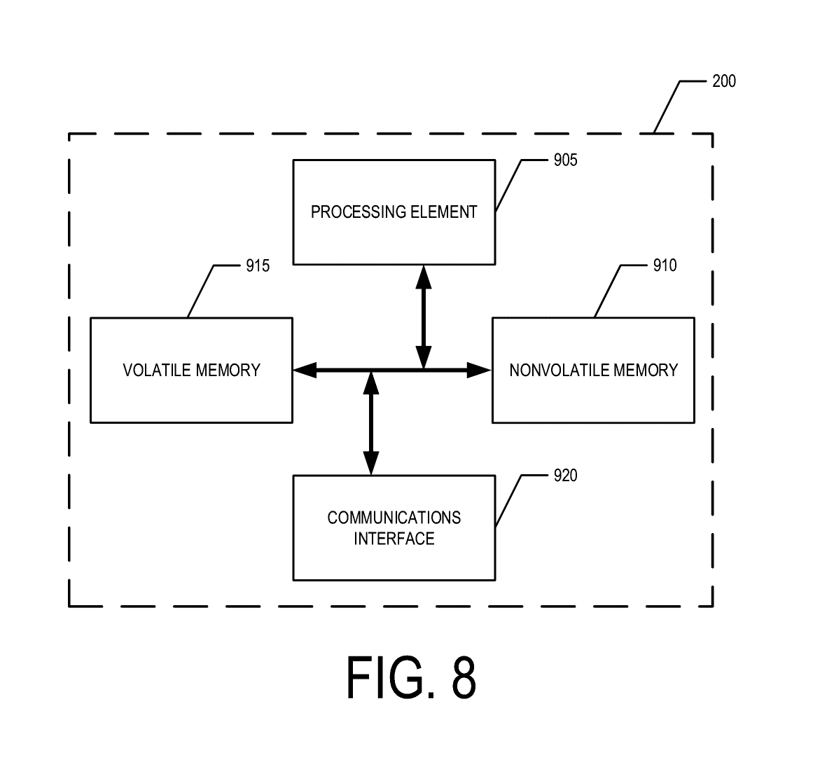

According to various embodiments of the present invention, electrical characteristics of an elliptical structure 101 may be determined/calculated. For example, a computing system 200 (for example, as shown in FIG. 8) may be used to calculate various electrical characteristic of an elliptical structure 101. For example, the drain to source current I_{DS}, an electric field E, energy transfer J, and/or other electrical characteristic for the elliptical structure 101 may be determined/calculated. By understanding how the electrical characteristics of the elliptical structure 101 differ from the idealized circular structure, improvements may be made in the functioning of the non-volatile memory device associated with the elliptical structure 101 (e.g., the cells of the string 100). For example, the electrical characteristics and understanding the difference between the elliptical structure versus the idealized circular structure of the non-volatile memory device or portions thereof may be utilized to improve the operation (e.g., operational speed, read speed, erase speed, programming speed, reduce the operational voltage to read, erase, and/or program, improve reliability, and/or the like) of the non-volatile memory device. In various embodiments, the actual shape of a GAA structure may be measured and/or a smoothed representation of the actual shape of the GAA structure may be determined/calculated via a method similar to that described in U.S. application Ser. No. 14/674,199, which is incorporated by reference its entirety herein.

### Calculating/Determining Electrical Characteristics

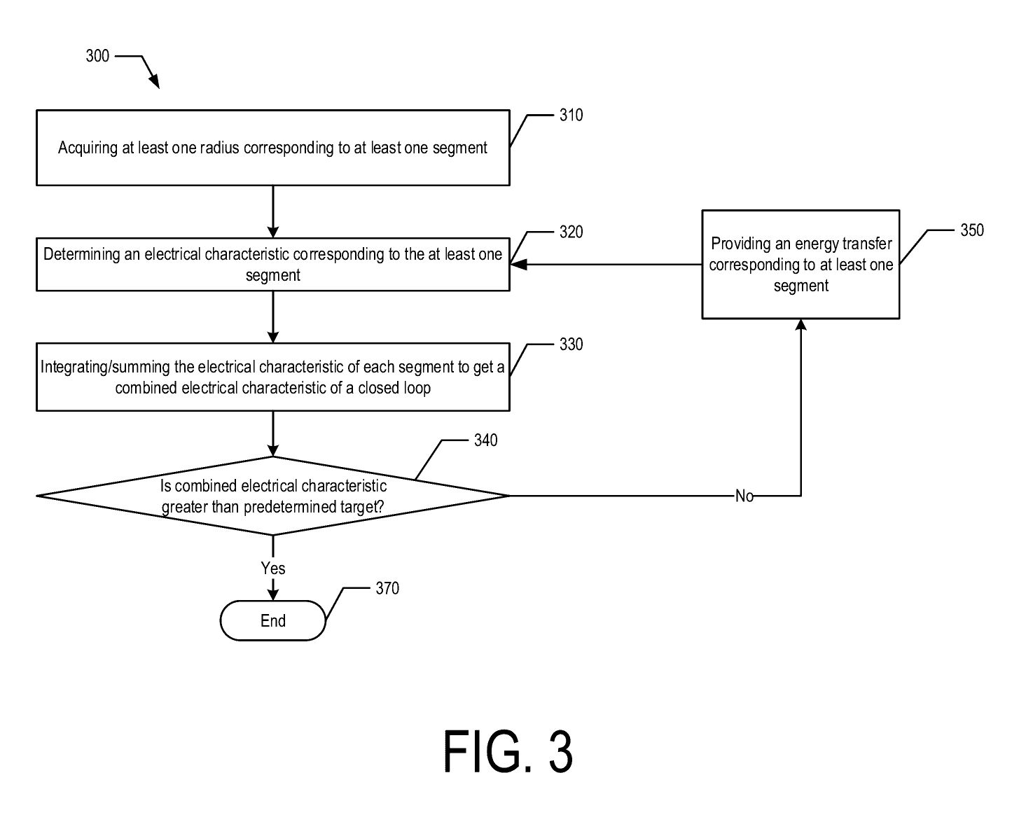

FIG. 3 is a flowchart illustrating a process 300 for determining electrical characteristics corresponding to a non-volatile memory device (e.g., 3D NAND flash memory) having a gate-all-around (GAA) structure according to an embodiment of the invention. For example, the process 300 may be used to determine/calculate the electrical characteristics of an elliptical structure 101 corresponding to a cell of a string 100. As will be appreciated by one of ordinary skill in the art, though the non-volatile memory device in example embodiments described herein comprises a flash memory such as a 3D NAND flash memory, the non-volatile memory device may comprise a 3D NOR, 3D ROM, 2D NAND, 2D NOR, MOS cells under regular arrangement, or any other device configured for voltage control under regular arrangement.

The process 300 beings at step 310 by determining/defining at least one segment 120 of a closed loop 130 and acquiring/calculating/determining the radius R of the segment 120. In various embodiments, a plurality of segments 120 that are structured to define a closed loop 130 may be determined/defined and the corresponding radii R may be acquired/calculated/determined. For example, the computer system 200 may determine/define at least one segment 120, the segment 120 comprising a portion of a closed loop 130. The computer system 200 may then acquire/calculate/determine the radius R of the segment 120.

In some embodiments, the acquisition of the at least one radius further comprises determining at least one radius according to an algorithm for curvature of

$$R ( {x}_{i} , {y}_{i} ) = \frac{{( {x}^{′2} + {y}^{′2} )}^{\frac{3}{2}}}{{x}^{′} {y}^{′′} - {x}^{″} {y}^{′}} = \frac{{( {a}^{2} {sin}^{2} ( t ) + {b}^{2} {cos}^{2} ( t ) )}^{\frac{3}{2}}}{ab} , \qquad ( 410 )$$

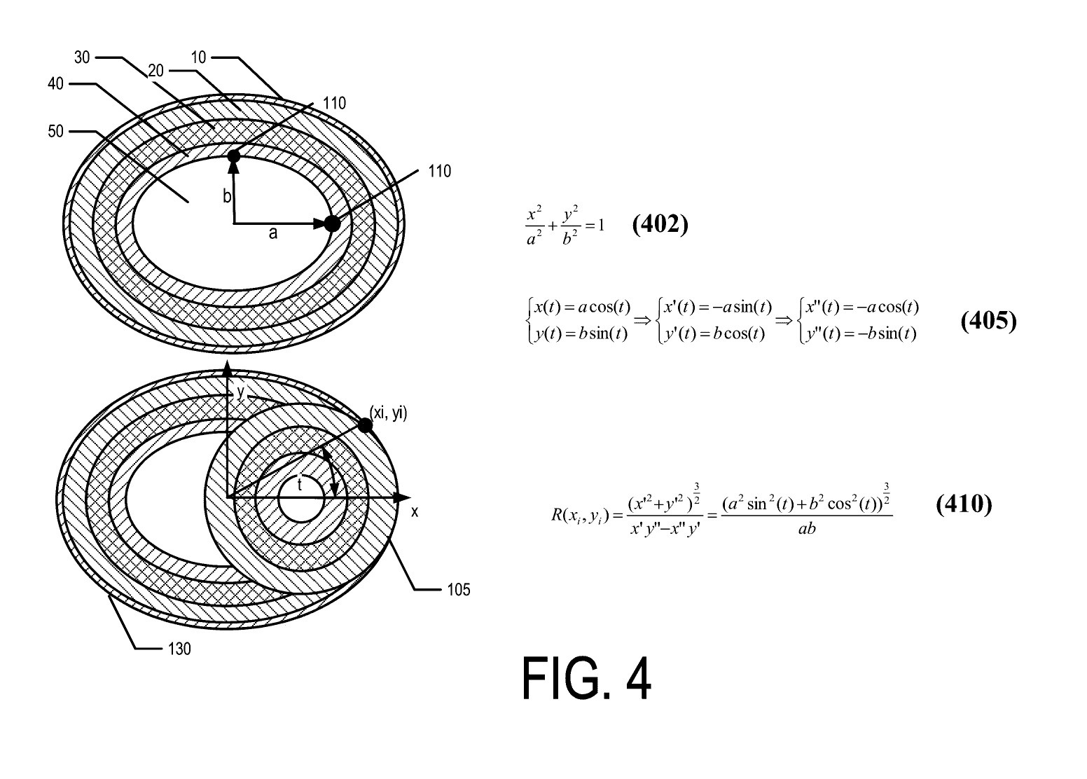

as illustrated in FIG. 4, where x′ is the first derivative of x with respect to the parameter t, y′ is the first derivative of y with respect to the parameter t, x″ is the second derivative of x with respect to the parameter t, and y″ is the second derivative of y with respect to the parameter t. R(xᵢ, yᵢ) is the radius corresponding to each point 110. In some embodiments, R(xᵢ, yᵢ) is derived/calculated/determined according to program algorithm 402 and/or 405 which provide relationships between x, y, the major axis of the ellipse a, the minor axis of the ellipse b, and the parameter t. As shown in FIG. 4, program algorithms 402 and 405 are

$$\begin{matrix}\frac{{x}^{2}}{{a}^{2}} + \frac{{y}^{2}}{{b}^{2}} = 1 \\ and & ( 402 ) \\ \{ \begin{matrix}x ( t ) = a cos ( t ) \\ y ( t ) = b sin ( t )\end{matrix} ⇒ \{ \begin{matrix}{x}^{′} ( t ) = - a sin ( t ) \\ {y}^{′} ( t ) = b cos ( t )\end{matrix} ⇒ \{ \begin{matrix}{x}^{″} ( t ) = - a cos ( t ) \\ {y}^{″} ( t ) = - b sin ( t )\end{matrix} . & ( 405 )\end{matrix}$$

Continuing to step 320, at least one electrical characteristic corresponding to the at least one segment is determined/calculated. For example, after acquiring at least the one radius corresponding to at least one segment 120, one or more electrical characteristics (e.g., a vertical electric field E(xᵢ,yᵢ, r), a current such as I_{DS(xi,yi)}) corresponding to the at least one segment 120, is determined/calculated. For example, after acquiring/calculating/determining the at least one radius R for the at least one segment 120, or possibly in response thereto, the computing system 200 may determine/calculate at least one electrical characteristic corresponding to the segment. In various embodiments the at least one electrical characteristic may be the drain to source current I_{DS}, an electric field E, energy transfer J, and/or other electrical characteristic. As will be appreciated, the electrical characteristic corresponding to each segment may be determined independently of, or concurrently with, another segment. For example, the computing system 200 may determine/calculate the at least one electrical characteristic for a plurality of segments 120 in series or by parallel computing architectures. In various embodiments, the electrical characteristic may depend on an applied voltage, electric field, and/or the like. For example, a particular value of an applied voltage (e.g., applied via a word line, bit line, channel line, and/or the like) may be assumed for calculating the electrical characteristic corresponding to that particular value of applied voltage.

Continuing to step 330, the electrical characteristic of each segment may be integrated/summed to determine/calculate a combined electrical characteristic of a closed loop 130. For example, the computing system 200 may determine/calculate a combined electrical characteristic of a closed loop 130 corresponding to the plurality of segments 120 by integrating/summing the electrical characteristic for each segment 120. For example, the computing system 200 may determine/calculate the drain to source current by integrating/summing the I_{DS}(xᵢ,yᵢ) corresponding to segment 120 at (xᵢ,yᵢ) such as

$${I}_{DS} = {\sum }_{i = 1}^{n} \frac{P ( {x}_{i} , {y}_{i} )}{n} \times \frac{1}{2 π R ( {x}_{i} , {y}_{i} )} \times {I}_{DS} ( {x}_{i} , {y}_{i} )$$

wherein P(xi,yi) is the perimeter of each segment and n is the number of segments 120 comprising the closed loop 130.

In some embodiments, the electrical characteristic (e.g., a current such as I_{DS}) corresponding to a closed loop 130 may be determined to determine another electrical characteristic of the closed loop 130. For example, the electrical current through the segment 120 corresponding to (xᵢ,yᵢ) I_{DS}(xᵢ,yᵢ) may be integrated to calculate/determine the current through the closed loop 130 (e.g., the closed loop of the elliptical structure) such that voltage distribution Vₜ for the closed loop 130 and/or one or more segments 120 may be extracted/determine/calculated.

At step 340, it is determined if the combined electrical characteristic of the closed loop 130 is higher than a predetermined target. For example, the computing system 200 may determine if the combined electrical characteristic of the closed loop 130 is greater than a predetermined target. For example, in various processes, it may be desired to cause the voltage distribution Vt of a cell of string 100 to be greater than a target voltage. For example, the target voltage may be a programming threshold voltage V_{PGM} corresponding to a state to which the cell of string 100 may be programmed. It may then be determined if the applied voltage raises the voltage distribution Vt of the corresponding cell above the programming threshold voltage V_{PGM}.

If, at step 340, it is determined that the electrical characteristic of the closed loop 130 is not higher than the predetermined target, the process 300 continues to step 350. At step 350, an energy transfer J_{FN}(xᵢ,yᵢ) for at least one segment is provided. For example, the energy transfer may correspond to a program operation or an erase operation. For example, the energy transfer J_{FN} may be determined/calculated and used to inform a new calculation of the electrical characteristic. For example, the determined/calculated energy transfer J_{FN} may be used to inform the selection of a new applied voltage that is used to re-calculate/determine the electrical characteristic for the at least one segment 120 and/or the closed loop 130 as the process 300 returns to step 320. As will be appreciated by one of ordinary skill in the art, the energy transfer corresponding to each segment may be determined independently of, or concurrently with, another segment (e.g., the energy transfer J_{FN}(xᵢ,yᵢ) corresponding to a segment 120 at (xᵢ,yᵢ) may be computed in series and/or parallel with the energy transfer J_{FN}(xⱼ,yⱼ) corresponding to another segment 120 at (xⱼ,yⱼ)

If, at step 340, it is determined that the determined/calculated electrical characteristic is greater than the predetermined target, the process 300 ends at step 370.

In embodiments wherein each of the plurality of segments has been analyzed, the process for determining electrical characteristics 300 may end at 370.

Following or integral with these steps, additional steps may be used to determine electrical characteristics 300. Such steps may include determining an electric field corresponding to at least one radius corresponding to a segment 120 and may include other additional steps depending upon the design and desired attributes of the non-volatile memory device. The electric field determined may correspond to a program operation or an erase operation. As should be understood, the analysis of the at least one electrical characteristic of the elliptical structure 101 corresponding to a cell of a string 100 may be used to more efficiently program, erase, read, or perform other functions on the cell. For example, an operating parameter may be defined for the cell based at least in part on the determined program and/or erase voltage.

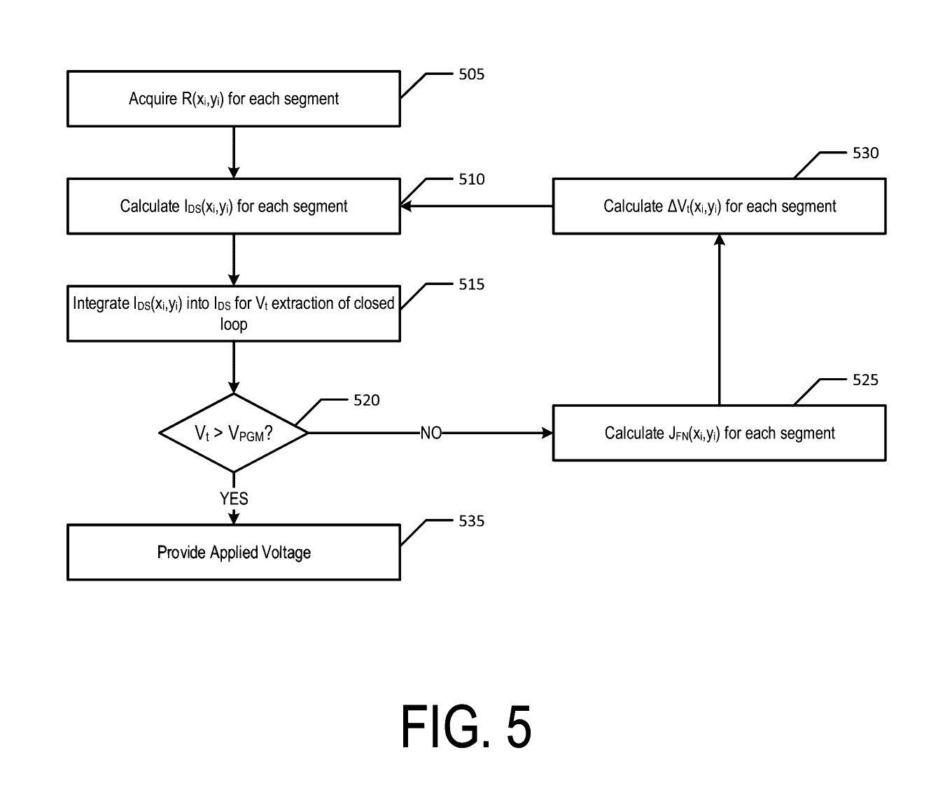

FIG. 5 provides a flow chart of an example of process 300 wherein the electrical characteristic computed is the voltage distribution Vₜ and the corresponding mechanism is programing the cell corresponding to the closed loop 130 It should be noted that in various embodiments, the mechanism may be erase. Starting at step 505, a plurality of segments 120 are defined such that the plurality of segments 120 are structured to form a closed loop 130 and a radius R for each segment 120 is acquired/determined/calculated. For example, the computing system 200 may define a plurality of segments 120 and acquire/determine/calculate a radius R for each segment.

At step 510, the segment current I_{DS}(xᵢ,yᵢ) for each of the plurality of segments 120 may be determined/calculated. For example, the computer system 200 may determine/calculate the segment current I_{DS}(xᵢ,yᵢ) for each segment 120. At step 515, the segment current I_{DS}(xᵢ,yᵢ) for each segment 120 is integrated/summed to determine the drain to source current I_{DS} for the closed loop 130 and the voltage distribution Vt of the closed loop 130 is extracted/determined/calculated. For example, the computing system 200 may integrate/sum the segment current I_{DS}(xᵢ,yᵢ) for each segment 120 to determine the drain to source current I_{DS} for the closed loop 130 and extract/determine/calculate the voltage distribution Vₜ of the closed loop 130 therefrom.

At step 520, it is determined if the voltage distribution Vₜ is greater than the programming voltage V_{PGM}. For example, the computing system 200 may determine if the voltage distribution Vₜ is greater than the programming voltage V_{PGM}.

If, at step 520, it is determined that the voltage distribution Vₜ is greater than the programming voltage V_{PGM}, then process continues to step 535. At step 535, the applied voltage input to the segment current I_{DS}(xᵢ,yᵢ) calculation or other output is provided. For example, the computer system 200 may provide an output. In one embodiment, the output is the applied voltage used to determine/calculate the segment current I_{DS}(xᵢ,yᵢ) for each of the plurality of segments 120. In some embodiments, the output may be displayed via a display associated with the computing system 200 (e.g., a monitor) or saved to a database, flat file, or other storage mechanism in communication with the computing system 200. For example, a chip controller associated with a memory device having one or more cells that may be represented by the elliptical structure 101 may be programmed to program the one or more cells in accordance with the applied voltage input to the segment current IDS(xᵢ,yᵢ) calculation. For example, an operating parameter may be defined for the cell based at least in part on the determined program and/or erase voltage.

If, at step 520, it is determined that the voltage distribution Vₜ is not greater than (e.g., is less than or possibly equal to) the programming voltage V_{PGM}, the process continues to step 525. At step 525, the energy transfer J_{FN}(xⱼ,yⱼ) for at least one segment 120 and/or for each segment 120 is determined/calculated. For example, the computing system 200 may determine/calculate the energy transfer J_{FN}(xⱼ,yⱼ) for at least one segment 120 and/or for each segment 120. At step 530, the change in the voltage distribution ΔVₜ (xᵢ,yᵢ) for at least one segment 120 and/or for each segment 120 and due to the energy transfer J_{FN}(xⱼ,yⱼ) for the corresponding segment 120 is determined/calculated. For example, the computer system may determine/calculate change in the voltage distribution ΔVₜ (xᵢ,yᵢ) due to the energy transfer J_{FN}(xⱼ,yⱼ) for the corresponding segment 120 for each segment that the energy transfer was determined/calculated for at step 525. The process may then use the determined/calculated change in the voltage distribution ΔVₜ (xᵢ,yᵢ) to determine a new assumed applied voltage to be provided as input at step 510. In some embodiments, change in the voltage distribution ΔVₜ(xᵢ,yᵢ) for each segment 120 may be integrated/summed to determine/calculate the change in the voltage distribution ΔVₜ for the closed loop 130 due to the energy transfer J_{FN}(xⱼ,yⱼ). In such embodiments, the change in the voltage distribution ΔVₜ for the closed loop 130 may be used to determine/calculate a new assumed applied voltage to be provided as input at step 510.

### Modeling Electrical Characteristics of the Elliptical Structure

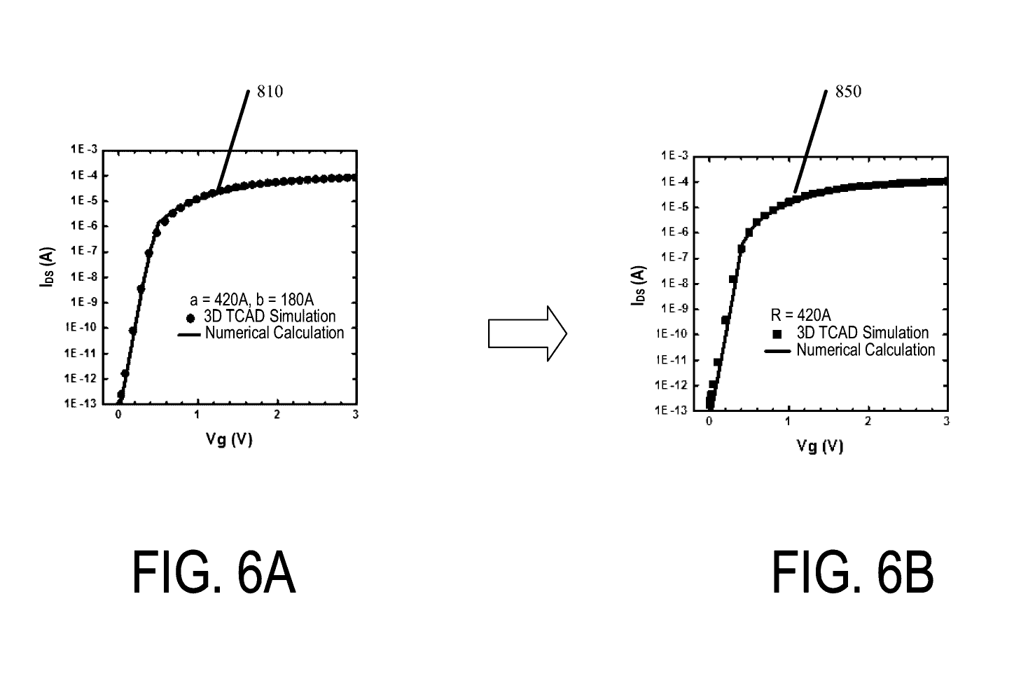

In various embodiments, the elliptical structure 101 may be modeled as a circular structure with an appropriate choice of the radius of the circular structure. For example, FIG. 6a illustrates an example current I_{DS} and applied voltage V_{g} relationship for an elliptical structure 101 and FIG. 6b illustrates an example corresponding I_{DS} and V_{g} relationship for an appropriate choice of a circular structure, according to an embodiment of the invention. In some embodiments, parameters (e.g., electrical characteristics such as electrical current, voltage distribution, energy transfer, electric field, and/or the like) corresponding to an elliptical structure 101 as illustrated at each point along the curve 810 in FIG. 6a may be similar to the parameters corresponding to an appropriate choice of circular structure, as shown by curve 850 in FIG. 6b. In various embodiments, the parameters corresponding to the circular structure may be acquired first. As demonstrated in FIGS. 6a and 6b at each point along the curve 810, similar parameters as those corresponding to curve 850 may generate an identical, or near-identical, curve 810 corresponding to an elliptical structure 101. For example, at curve 810 when voltage Vg=1V, a current Id=1.5E⁻⁵ A is generated. Similarly, with reference to curve 850, when voltage Vg=1V, a current Id=1.5E⁻⁵A also is generated. In this regard, the elliptical structure 101, though a non-circular structure, may be fit (e.g., matched) to a circular structure based on the example embodiments provided herein. To that end, the electrical characteristics such as current and voltage corresponding to each of the plurality of segments may be determined such that the composition of current at an identical, or near identical, voltage corresponding to a closed loop of an elliptical structure may be determined. For example, the electrical characteristics of the elliptical structure having a major axis a and a minor axis b may be modeled/calculated/determined as if they were the electrical characteristics of a circular structure having a radius a. This relationship may hold for certain ranges of the electrical characteristics, applied voltage V_{G}, minor axis b, and/or the like.

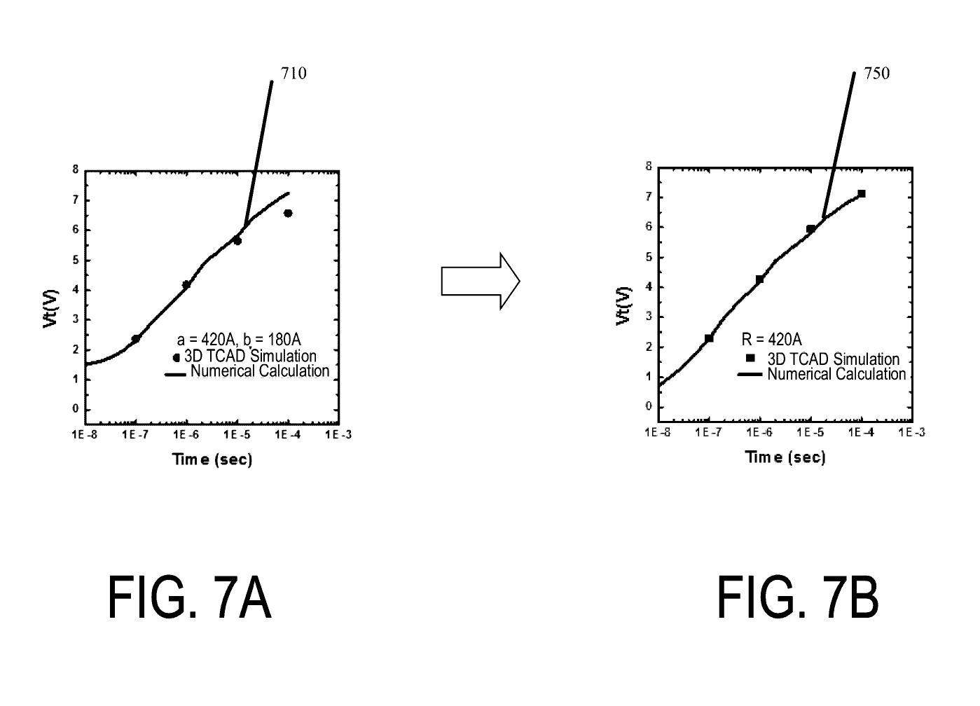

FIGS. 7a and 7b illustrate example graphs of voltage distribution corresponding to an elliptical structure 101 and an appropriately chosen circular structure, respectively, according to an embodiment of the invention. In some embodiments, parameters (e.g., electrical characteristics corresponding to program operation) corresponding to a circular structure as illustrated at each point along the curve 750 in FIG. 7b may be acquired first. As demonstrated in FIG. 7a at each point along the curve 710, similar parameters for the elliptical structure 101, corresponding to curve 750, may generate an identical, or near-identical, curve 710 corresponding to the parameters of an appropriately chosen circular structure. For example, at curve 710 at Time=1.5E⁻⁵, a voltage distribution Vt=6V is generated. Similarly, with reference to curve 750, at Time=1.5E⁻⁵, a voltage distribution Vt=6V also is generated. In this regard, one or more electrical characteristics a non-circular structure (e.g., the elliptical structure 101 ) may be modeled/determined/calculated as the electrical characteristics of an appropriately chosen circular structure based on the example embodiments provided herein. As previously noted, the electrical characteristics of the elliptical structure having a major axis a and a minor axis b may be modeled/calculated/determined as if they were the electrical characteristics of a circular structure having a radius a. This relationship may hold for certain ranges of the electrical characteristics, applied voltage V_{G}, minor axis b, and/or the like. To that end, the electrical characteristics such as program and/or erase voltage distribution may be determined via an integration of transient by time. For example, an operating parameter may be defined for the cell based at least in part on the determined program and/or erase voltage.

As will be appreciated by one of ordinary skill in the art, in some example embodiments, a method for controlling voltage distribution may correspond to any of a gate, insulator, channel, or any other device configured for MOS characteristics (e.g., I_{DS}-V_{g}) though flash memory is included in the example embodiments described herein.

An aspect of the invention provides a non-volatile memory device configured according to a method of the invention.

### Exemplary Computing System

FIG. 8 provides a schematic of a computing system 200 according to one embodiment of the present invention. In general, the terms computing system, computing entity, entity, device, system, and/or similar words used herein interchangeably may refer to, for example, one or more computers, computing entities, desktop computers, mobile phones, tablets, phablets, notebooks, laptops, distributed systems, wearable items/devices, servers or server networks, processing devices, processing entities, the like, and/or any combination of devices or entities adapted to perform the functions, operations, and/or processes described herein. Such functions, operations, and/or processes may include, for example, transmitting, receiving, operating on, processing, displaying, storing, determining, creating/generating, monitoring, evaluating, comparing, and/or similar terms used herein interchangeably. In one embodiment, these functions, operations, and/or processes can be performed on data, content, information, and/or similar terms used herein interchangeably.

As indicated, in one embodiment, the computing system 200 may also include one or more communications interfaces 920 for communicating with various computing entities, such as by communicating data, content, information, and/or similar terms used herein interchangeably that can be transmitted, received, operated on, processed, displayed, stored, and/or the like.

As shown in FIG. 8, in one embodiment, the computing system 200 may include or be in communication with one or more processing elements 905 (also referred to as processors, processing circuitry, and/or similar terms used herein interchangeably) that communicate with other elements within the computing system 200 via a bus, for example. As will be understood, the processing element 905 may be embodied in a number of different ways. For example, the processing element 905 may be embodied as one or more complex programmable logic devices (CPLDs), microprocessors, multi-core processors, coprocessing entities, application-specific instruction-set processors (ASIPs), and/or controllers. Further, the processing element 905 may be embodied as one or more other processing devices or circuitry. The term circuitry may refer to an entirely hardware embodiment or a combination of hardware and computer program products. Thus, the processing element 905 may be embodied as integrated circuits, application specific integrated circuits (ASICs), field programmable gate arrays (FPGAs), programmable logic arrays (PLAs), hardware accelerators, other circuitry, and/or the like. As will therefore be understood, the processing element 905 may be configured for a particular use or configured to execute instructions stored in volatile or non-volatile media or otherwise accessible to the processing element 905. As such, whether configured by hardware or computer program products, or by a combination thereof, the processing element 905 may be capable of performing steps or operations according to embodiments of the present invention when configured accordingly.

In one embodiment, the computing system 200 may further include or be in communication with non-volatile media (also referred to as non-volatile storage, memory, memory storage, memory circuitry and/or similar terms used herein interchangeably). In one embodiment, the non-volatile storage or memory may include one or more non-volatile storage or memory media 910 as described above, such as hard disks, ROM, PROM, EPROM, EEPROM, flash memory, MMCs, SD memory cards, Memory Sticks, CBRAM, PRAM, FeRAM, RRAM, SONOS, racetrack memory, and/or the like. As will be recognized, the non-volatile storage or memory media may store databases, database instances, database management system entities, data, applications, programs, program modules, scripts, source code, object code, byte code, compiled code, interpreted code, machine code, executable instructions, and/or the like. The term database, database instance, database management system entity, and/or similar terms used herein interchangeably may refer to a structured collection of records or information/data that is stored in a computer-readable storage medium, such as via a relational database, hierarchical database, and/or network database.

In one embodiment, the computing system 200 may further include or be in communication with volatile media (also referred to as volatile storage, memory, memory storage, memory circuitry and/or similar terms used herein interchangeably). In one embodiment, the volatile storage or memory may also include one or more volatile storage or memory media 915 as described above, such as RAM, DRAM, SRAM, FPM DRAM, EDO DRAM, SDRAM, DDR SDRAM, DDR2 SDRAM, DDR3 SDRAM, RDRAM, RIMM, DIMM, SIMM, VRAM, cache memory, register memory, and/or the like. As will be recognized, the volatile storage or memory media may be used to store at least portions of the databases, database instances, database management system entities, data, applications, programs, program modules, scripts, source code, object code, byte code, compiled code, interpreted code, machine code, executable instructions, and/or the like being executed by, for example, the processing element 905. Thus, the databases, database instances, database management system entities, data, applications, programs, program modules, scripts, source code, object code, byte code, compiled code, interpreted code, machine code, executable instructions, and/or the like may be used to control certain aspects of the operation of the computing system 200 with the assistance of the processing element 905 and operating system.

As indicated, in one embodiment, the computing system 200 may also include one or more communications interfaces 920 for communicating with various computing entities, such as by communicating data, content, information, and/or similar terms used herein interchangeably that can be transmitted, received, operated on, processed, displayed, stored, and/or the like. Such communication may be executed using a wired information/data transmission protocol, such as fiber distributed information/data interface (FDDI), digital subscriber line (DSL), Ethernet, asynchronous transfer mode (ATM), frame relay, information/data over cable service interface specification (DOCSIS), or any other wired transmission protocol. Similarly, the computing system 200 may be configured to communicate via wireless external communication networks using any of a variety of protocols, such as GPRS, UMTS, CDMA2000, 1xRTT, WCDMA, TD-SCDMA, LTE, E-UTRAN, EVDO, HSPA, HSDPA, Wi-Fi, WiMAX, UWB, IR protocols, Bluetooth protocols, USB protocols, and/or any other wireless protocol.

Although not shown, the computing system 200 may include or be in communication with one or more input elements, such as a keyboard input, a mouse input, a touch screen/display input, audio input, pointing device input, joystick input, keypad input, and/or the like. The computing system 200 may also include or be in communication with one or more output elements (not shown), such as audio output, video output, screen/display output, motion output, movement output, and/or the like.

As will be appreciated, one or more of the computing system 200 components may be located remotely from other computing system 200 components, such as in a distributed system. Furthermore, one or more of the components may be combined and additional components performing functions described herein may be included in the computing system 200. Thus, the computing system 200 can be adapted to accommodate a variety of needs and circumstances.

### Conclusion

As should be appreciated, the embodiments may be implemented as methods, apparatus, systems, or computer program products. Accordingly, the embodiments may take the form of an entirely hardware embodiment, an entirely software embodiment, or an embodiment combining software and hardware aspects. Furthermore, the various implementations may take the form of a computer program product on a computer-readable storage medium having computer-readable program instructions (e.g., computer software) embodied in the storage medium. Any suitable computer-readable storage medium may be utilized including hard disks, CD-ROMs, optical storage devices, or magnetic storage devices.

Various embodiments are described herein with reference to block diagrams and flowchart illustrations of methods, apparatus, systems, and computer program products. It should be understood that each block of the block diagrams and flowchart illustrations, respectively, can be implemented by computer program instructions, e.g., as logical steps or operations. These computer program instructions may be loaded onto a general purpose computer, special purpose computer, or other programmable data processing apparatus to produce a machine, such that the instructions which execute on the computer or other programmable data processing apparatus implement the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including computer-readable instructions for implementing the functionality specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide operations for implementing the functions specified in the flowchart block or blocks.

Accordingly, blocks of the block diagrams and flowchart illustrations support various combinations for performing the specified functions, combinations of operations for performing the specified functions, and program instructions for performing the specified functions. It should also be understood that each block of the block diagrams and flowchart illustrations, and combinations of blocks in the block diagrams and flowchart illustrations, can be implemented by special purpose hardware-based computer systems that perform the specified functions or operations, or combinations of special purpose hardware and computer instructions.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

That which is claimed:

1. A string of 3D flash memory cells, the string comprising:
a core extending along an axis of the string, the core having an elliptical cross section in a plane perpendicular to the axis;
a plurality of word lines, each word line disposed around a part of the core, the plurality of word lines spaced along the axis, and each word line corresponding to one of the memory cells.

2. The string of 3D flash memory cells of claim 1, the string comprising:
a first cell having a first elliptical cross section in a first plane perpendicular to the axis, the elliptical cross section defining a first major axis and a first minor axis; and
a second cell having a second elliptical cross section in a second plane perpendicular to the axis, the elliptical cross section defining a second major axis and a second minor axis, wherein:
the first cell and the second cell are neighboring cells, and
at least one of the first and second major axes are different or the first and second minor axes are different.

3. The string of 3D flash memory cells of claim 1, wherein the core comprises:
a channel region extending along the axis,
a blocking layer about the channel region,
a trapping layer about the blocking layer, and
a tunnel layer about the trapping layer.

4. The string of 3D flash memory cells of claim 1, wherein the core has an external surface defining an angle less than less than 90° to the plane perpendicular to the axis.

5. The string of 3D flash memory cells of claim 3, wherein the blocking layer is made of oxide and is approximately 7 mm thick.

6. The string of 3D flash memory cells of claim 3, wherein the tunnel layer is made of oxide and is approximately 5 mm thick.

7. The string of 3D flash memory cells of claim 3, wherein each word line is around a portion of the tunnel layer.

8. The string of 3D flash memory cells of claim 1, wherein at least one electrical characteristic of each cell may be modeled as the electrical characteristic of a corresponding structure having a circular cross section.

9. The string of 3D flash memory cells of claim 8, wherein the at least one electrical characteristic is at least one of voltage distribution, drain to source current, energy transfer, and electric field.

10. The string of 3D flash memory cells of claim 8, wherein the structure having a circular cross section is defined by a radius approximately equal to a major axis defined by the elliptical cross section of the corresponding cell.

11. A method for improving a performance of a 3D non-volatile memory device comprising a plurality of cells having a gate-all-around structure, the method comprising:
determining at least one operating parameter of at least one of the plurality of cells, determining the at least one operating parameter comprising:
determining at least one electrical characteristic of the at least one of the plurality of cells, determining the at least one electrical characteristic comprising:
defining a plurality of segments, the plurality of segments structured to define a closed loop, the closed loop approximating the circumference of the cross section of the cell;
acquiring a radius of curvature for each of the plurality of segments;
determining a value for the electrical characteristic for each of the plurality of segments based at least in part on the radius of curvature corresponding to the segment; and
summing the values for the electrical characteristic for each of the plurality of segments to determine the electrical characteristic for the closed loop;
defining an operating parameter of the at least one of the plurality of cells based at least in part on the determined electrical characteristic for the closed loop; and
causing at least one function to be performed on the cell in accordance with the defined operating parameter.

12. The method of claim 11, wherein the electrical characteristic is a drain to source current,
the step of determining at least one operating parameter of at least one of the plurality of cells further comprising:
determining a voltage distribution corresponding to the closed loop based at least in part the drain to source current for the closed; and
the operating parameter being defined in response to determining that the voltage distribution is greater than a target voltage.

13. The method of claim 12, wherein the target voltage is one of a program voltage or an erase voltage.

14. The method of claim 11, wherein the closed loop is an ellipse.

15. The method of claim 11, wherein the closed loop is a non-planar structure.

16. The method of claim 11, wherein the plurality of cells are arranged along one or more strings, each string comprising:
a core extending along an axis of the string, the core having an elliptical cross section in a plane perpendicular to the axis;
a plurality of word lines, each word line disposed around a part of the core, the plurality of word lines spaced along the axis, and each word line corresponding to one of the memory cells.

17. The method of claim 16 wherein the plurality of cells comprises:
a first cell having a first elliptical cross section in a first plane perpendicular to the axis, the elliptical cross section defining a first major axis and a first minor axis; and
a second cell having a second elliptical cross section in a second plane perpendicular to the axis, the elliptical cross section defining a second major axis and a second minor axis,
wherein:
the first cell and the second cell are on the same string,
the first cell and the second cell are neighboring cells, and
at least one of the first and second major axes are different or the first and second minor axes are different.

18. The method of claim 16, wherein the core comprises:
a channel region extending along the axis,
a blocking layer about the channel region,
a trapping layer about the blocking layer, and
a tunnel layer about the trapping layer.

19. The method of claim 11, wherein at least one electrical characteristic of each cell may be modeled as the electrical characteristic of a corresponding structure having a circular cross section.

20. The method of claim 19, wherein the structure having a circular cross section is defined by a radius approximately equal to a major axis defined by the elliptical cross section of the corresponding cell.
